(19) United States
(12) Patent Application Publication
(10) Pub. No.: US 2025/0356912 A1
(43) Pub. Date: Nov. 20, 2025

(54) ACCELERATED BITLINE READ

(71) Applicant: APPLE INC., CUPERTINO, CA (US)

(72) Inventors: QING DONG, CUPERTINO, CA (US); ARAVIND KANDALA, SAN JOSE, CA (US); BHARAN GIRIDHAR, PALO ALTO, CA (US); HEMANGI U. GAJJEWAR, SUNNYVALE, CA (US)

(21) Appl. No.: 19/040,564

(22) Filed: Jan. 29, 2025

Related U.S. Application Data
(60) Provisional application No. 63/647,527, filed on May 14, 2024.

(51) Int. Cl. G11C 11/419

(52) U.S. Cl. CPC G11C 11/419

(57) ABSTRACT

A circuit configured for an accelerated read of bitlines includes a first bitline; a second bitline; and a bitcell coupled to the first and second bitline and storing a value. The circuit also includes a accelerated discharge circuit coupled to the first and second bitline and configured to accelerate reading the value stored in the bitcell through the first and second bitline. In some examples, the accelerated discharge circuit initiates a discharge of the first and second bitline prior to the read. In some examples, the accelerated discharge circuit initiates a discharge of the first and second bitline in parallel to the read.

### CROSS-REFERENCE TO RELATED APPLICATIONS

This application is a non-provisional application for patent entitled to a filing date and claiming the benefit of earlier-filed U.S. Provisional Patent Application No. 63/647,527, filed May 14, 2024, herein incorporated by reference in its entirety.

### BACKGROUND

### Technical Field

This disclosure is directed to electronic circuits, and more particularly, circuits for reading values stored in bitcells of a memory.

### Description of the Related Art

Many integrated circuits (ICs) implement on-chip memories in the form of SRAM (Static Random Access Memory), such as cache and register files. Cache and register files may provide memory close to various functional accelerated discharge circuits that need fast access thereto. For example, processor cores typically include a cache and/or register files to implement architected registers, as well as extra registers used in, e.g., register renaming schemes. Graphics processors may also implement caches and register files near graphics processing cores.

A typical SRAM may include a number of bitcells, each arranged to store a single bit of information. The total number of bitcells in an SRAM may be divided into a number of subsets of bitcells. The bitcells of a given subset of bitcells may be coupled to a corresponding column decoder circuit that may select one bitcell of the subset during a read of data stored therein. The data in a selected bitcell may be output to a circuit that includes a dynamic sense amplifier and a latch circuit. Thus, a given data bit from a selected bitcell may be conveyed through a column decoder, a sense amplifier, and may be output via a latch circuit.

### SUMMARY

Various circuits, apparatus, and methods for performing accelerated reads in memory are disclosed herein. Such an example circuit configured for accelerated reads in a memory includes: a first bitline, a second bitline, a bitcell coupled to the first and second bitline and storing a value; and a accelerated discharge circuit coupled to the first and second bitline. In such an example circuit the accelerated discharge circuit may be configured to accelerate reading the value stored in the bitcell through the first and second bitline.

Example apparatus for performing accelerated reads in memory may include a control circuit and memory coupled to the control circuit. The memory may include a first bitline, a second bitline, a bitcell coupled to the first and second bitline and storing a value, and a accelerated discharge circuit coupled to the first and second bitline. The accelerated discharge circuit may be configured to accelerate reading the value stored in the bitcell through the first and second bitline. In such an example apparatus, the control circuit may be configured to pre-charge the first and second bitline, engage the accelerated discharge circuit to begin a discharge of the first and second bitline; and perform a read of the value of the bitcell through the first and second bitlines.

Example methods for performing accelerated reads may be carried out with a memory that includes include a first bitline, a second bitline, a bitcell coupled to the first and second bitline and storing a value, and an accelerated discharge circuit coupled to the first and second bitline. The method may include pre-charging the first and second bitline, engaging the accelerated discharge circuit to begin a discharge of the first and second bitline, and performing a read of the value of the bitcell through the first and second bitlines. In some examples, engaging the accelerated discharge circuit may be carried out by initiating a discharge of the first and second bitline prior to beginning the read. In some other examples, engaging the accelerated discharge circuit may be carried out by initiating a discharge of the first and second bitline in parallel with the read.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 is a block diagram of one embodiment of an integrated circuit (IC) having a register file, in accordance with one or more embodiments of the present disclosure.

FIG. 2 is a block diagram of one embodiment of a register file, in accordance with one or more embodiments of the present disclosure.

FIG. 3 is a block diagram illustrating an example memory configured for accelerator bitline reads in accordance with one or more embodiments of the present disclosure.

FIG. 4 is a block diagram illustrating an example memory in a first configuration, in accordance with one or more embodiments of the present disclosure.

FIG. 5A depicts a timing diagram illustrating an example accelerated read operation of the bitcell of the memory of FIG. 4 in which the value stored in the bitcell is a zero.

FIG. 5B depicts a timing diagram illustrating an example read operation of the bitcell of the memory of FIG. 4 in which the value stored in the bitcell is a one.

FIG. 6 is a block diagram illustrating an example memory in a second configuration, in accordance with one or more embodiments of the present disclosure.

FIG. 7A depicts a timing diagram illustrating an example accelerated read operation of the bitcell of the memory of FIG. 6 in which the value stored in the bitcell is a zero.

FIG. 7B depicts a timing diagram illustrating an example read operation of the bitcell of the memory of FIG. 6 in which the value stored in the bitcell is a one.

FIG. 8 is a block diagram illustrating an example memory in a third configuration, in accordance with one or more embodiments of the present disclosure.

FIG. 9A depicts a timing diagram illustrating an example accelerated read operation of the bitcell of the memory of FIG. 8 in which the value stored in the bitcell is a zero.

FIG. 9B depicts a timing diagram illustrating an example read operation of the bitcell of the memory of FIG. 8 in which the value stored in the bitcell is a one.

FIG. 10 is a block diagram illustrating an example memory in a fourth configuration, in accordance with one or more embodiments of the present disclosure.

FIG. 11A depicts a timing diagram illustrating an example accelerated read operation of the bitcell of the memory of FIG. 10 in which the value stored in the bitcell is a zero.

FIG. 11B depicts a timing diagram illustrating an example read operation of the bitcell of the memory of FIG. 10 in which the value stored in the bitcell is a one.

FIG. 12A is a flow chart illustrating an example method of accelerating a bitline read in which the bitlines begin discharging prior to initiating a read operation in accordance with one or more embodiments of the present disclosure.

FIG. 12B is a flow chart illustrating another example method of accelerating a bitline read in which an accelerated discharge of the bitlines is initiated in parallel with a read operation in accordance with one or more embodiments of the present disclosure.

FIG. 13 is a block diagram of one embodiment of an example system, in accordance with one or more embodiments of the present disclosure.

In the following description, numerous specific details are set forth to provide a thorough understanding of the disclosed embodiments. One having ordinary skill in the art, however, should recognize that aspects of disclosed embodiments might be practiced without these specific details. In some instances, well-known circuits, structures, signals, computer program instruction, and techniques have not been shown in detail to avoid obscuring the disclosed embodiments.

### DETAILED DESCRIPTION OF EMBODIMENTS

As discussed above, many integrated circuits (ICs) implement on-chip memories in the form of SRAM, such as caches and register files. An example register file may include a number of bitcells, and each bitcell may store a single bit of information. The data/information stored in a bitcell may be read by accessing one or more bitlines memory, as discussed in more detail below.

The embodiments, examples, and/or implementation discussed herein may provide memories with bitcells that allow for faster reads of the bitcells. The memories may include various field-effect-transistors (FETs), capacitors, etc., that may allow different lines of the bitcell to discharge or decrease voltage more quickly, which may provide for faster reads of the bitcell, as discussed in more detail below.

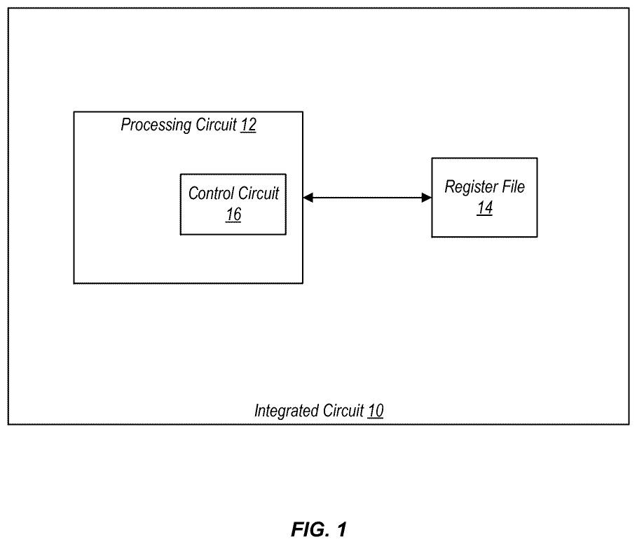

FIG. 1 is a block diagram of one embodiment of an integrated circuit (IC) 10 having a register file, in accordance with one or more embodiments of the present disclosure. IC 10 as shown herein is a simplified example provided for the sake of illustration, but is not meant to be limiting to any particular IC embodiment.

As illustrated in FIG. 1, IC 10 includes a processing circuit 12, which is coupled to a register file 14. The processing circuit 12 may be one of a number of different types of processing circuits, including general purpose processing circuits, graphics processing circuits, digital signal processing circuits, and so forth. Register file 14 may be used to store information used by processing circuit 12 in performing operations (e.g., operands for particular instructions that are executed by one embodiment). Additionally, register file 14 may also store the results of operations performed by processing circuit 12.

In the example of FIG. 1, processing circuit 12 includes control circuit 16 that is configured to control writing from and reading to register file 14. The control circuit may be configured to control write lines, bit lines, column select lines, address and multiplexer lines.

Although not shown herein, IC 10 may also include various input/output (I/O) circuits for conveying information thereto and therefrom. For example, information from register file 14 may be conveyed, directly or indirectly, to another memory (e.g., a cache memory) in the system in which IC 10 is implemented. Similarly, register file 14 may receive information from sources external to IC 10, either directly or indirectly.

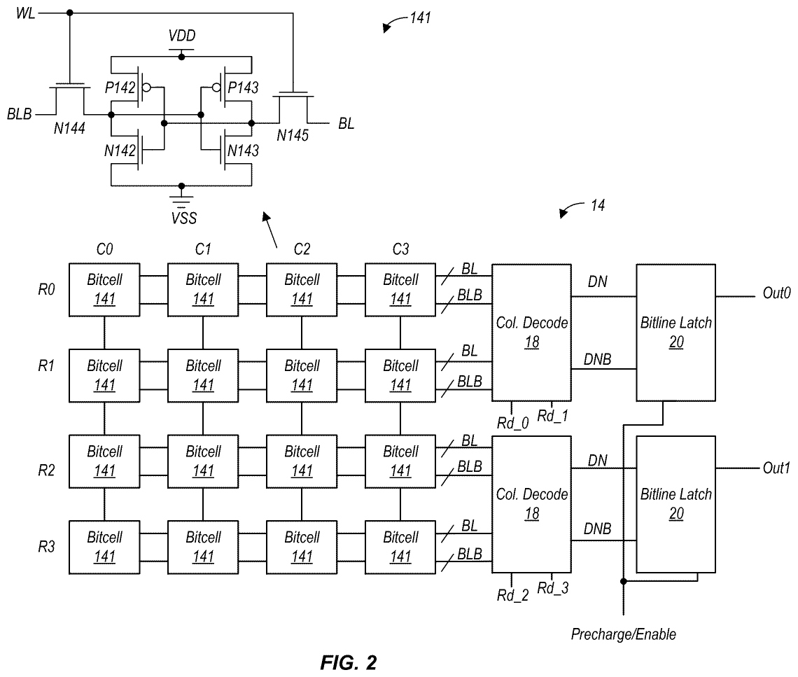

FIG. 2 is a block diagram of one embodiment of a register file, in accordance with one or more embodiments of the present disclosure. As with FIG. 1, the embodiment of register file 14 shown in FIG. 2 is simplified for the sake of illustration. Embodiments having a different number of bitcells, rows, and/or columns are possible and contemplated, and thus FIG. 2 is not intended to be limiting.

In the illustrated embodiment, register file 14 includes a number of bitcells 141. Each of the bitcells in this embodiment is a six-transistor (e.g., FET) or 6T, bitcell. A schematic diagram of an exemplary 6T bitcells is also shown in FIG. 2. In the schematic diagram, passgate transistors N144 and N145 (e.g., passgate FETs), when activated, couple the internal portion of the cell to the complementary bit line (BLB) and the true bit line (BL), respectively. These passgate transistors may be activated for both write and read operations. Transistors P142, P143, N142, and N143 (e.g., FETs) form two cross-coupled inverters that may hold both true and complementary logic values that have been written into the bitcell 141. The transistors illustrated and discussed herein may also be referred to as FETs.

Although the embodiment discussed herein uses 6T bitcells, embodiments that use other types of bitcells are also possible and contemplated.

The bitcells 141 in this exemplary embodiment are arranged into four rows (R0-R3) of four columns (C0-C3) each. The bit lines BL and BLB of each of the bitcells 141 are coupled to a corresponding column decoder circuit 18. Each of the bitcells 141 in a given column is coupled to receive a common word line signal (e.g., the bitcells 141 in C0 are each coupled to receive a word line signal WL0). When a word line signal is asserted, the passgates of the correspondingly coupled bitcells 141 are activated and thus the bitlines are coupled to the internal nodes defined by the cross-coupled inverters. During write operations, a given word line may be activated, and data may be conveyed into the internal nodes of the affected bitcells 141 through the passgate transistors. During read operations, a given word line may be activated and data stored in the affected bitcells may be conveyed onto the bit lines through the passgate transistors.

Each instance of a column decoder circuit 18 corresponds to a pair of bitcell rows in this embodiment and is configured to select a cell from one of the rows. During a read and write operations, a single one of the word lines may be activated to select each of the bitcells in the corresponding column. The remaining word lines may remain inactive. Each bitcell 141 in the selected column may convey data via its bitlines to the correspondingly coupled one of the column decoder circuits 18. Each column decoder 18 may select one of the bitcells 141. For example, the first (upper) column decoder circuit 18 may select a bitcell 141 in either Row 0 or Row 1 of the active column (by activating one of Rd_0 or Rd_1), while the second (lower) column decoder circuit 18 may select a bitcell 141 from either Row 2 or Row 3 of the active column (by activating one of Rd_2 or Rd_3). Thus, the column decoder circuit 18 shown in this embodiment are 2-1 decoders, although other types (e.g., 4-1, 8-1, etc.) are possible and contemplated. Each selected bitcell 141 may convey its stored data via the true and complementary bit lines to the corresponding bitline latch 20 via the associated differential signal nodes DN and DNb. Each bitline latch circuit 20 may provide an output bit as a single-ended signal. As explained in further detail below, one embodiment of the bitline latch 20 may be implemented without the use of a sense amplifier that is commonly used in corresponding circuits of prior art embodiments. This can result in significant area savings.

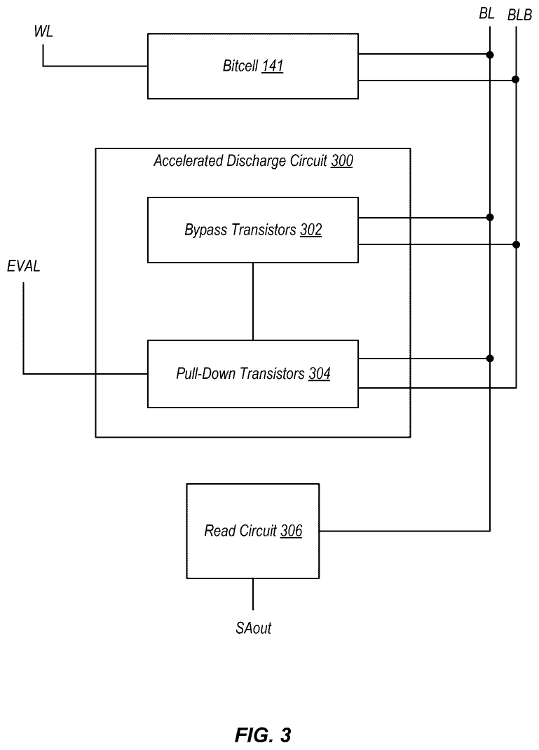

For further explanation, FIG. 3 sets forth a block diagram illustrating an example memory configured for accelerator bitline reads in accordance with one or more embodiments of the present disclosure. The example of FIG. 3 includes a bitcell 141 which may be implemented in a manner similar to the bitcell 141 of FIG. 2. The example bitcell 141 may store either a value of one or zero.

The example memory of FIG. 3 also a read circuit 306. The read circuit may be implemented with any components that enable reading the value of the of the bitline (BL), bitline bar (BLB), or both. In some embodiments, for example, an inverter is coupled to BL and outputs SAout.

To read the value stored in a bitcell 141, both bitlines, BL and BLB, are precharged to a high voltage, referred to herein as VDD. Next, a WL signal is applied to the bitcell which begins a discharge of either BL or BLB depending on the value stored in the bitcell. If the value stored in the bitcell 141 is a zero, BL will be discharged to ground (or VSS) while BLB remains at VDD. If the value stored in the bitcell 141 is a one, BLB will be discharged to ground while BL remains at VDD. The more rapidly a bitline discharges to zero the more quickly the value stored in the bitcell can be read.

The example memory of FIG. 3 is configured for accelerated bitline reads in accordance with embodiments described herein. To that end, the example memory of FIG. 3 also includes accelerated discharge circuit 300. Accelerated discharge circuit 300 includes one or more bypass transistors 302 and one or more pull-down transistors 304. The pull-down transistors 304 are controlled by a control signal, EVAL. When activated by the EVAL control signal, the pull-down transistors begin to discharge one or more of the bitlines. This discharge may be initiated (but not completed) prior to the WL signal being applied and causing the discharge described above. That is, in some embodiments, the pull-down transistors 304 precondition the bitlines by beginning a discharge before the WL signal is applied (before the read operation initiates). In some other embodiments, the EVAL control signal may be applied in parallel with the WL signal such that the pull-down transistors 304 provide accelerated discharge of one or more of the bitlines during the read operation.

To ensure accurate reading of the value stored in the bitcell, neither bitline should be discharged completely prior to the application of the WL signal. Additionally, only one of the two lines should be completely discharged at given time. That is, BL and BLB should not be completely discharged at the same time. The bypass transistors 302 of the accelerated discharge circuit 300 of FIG. 3 are configured to monitor the value of BL and BLB and bypass or otherwise deactivate the pull-down transistors 304 when BL and/or BLB is discharged below a threshold. In this way, the bypass transistors 302 ensure that the pull-down transistors 304 do not discharge either bitline completely.

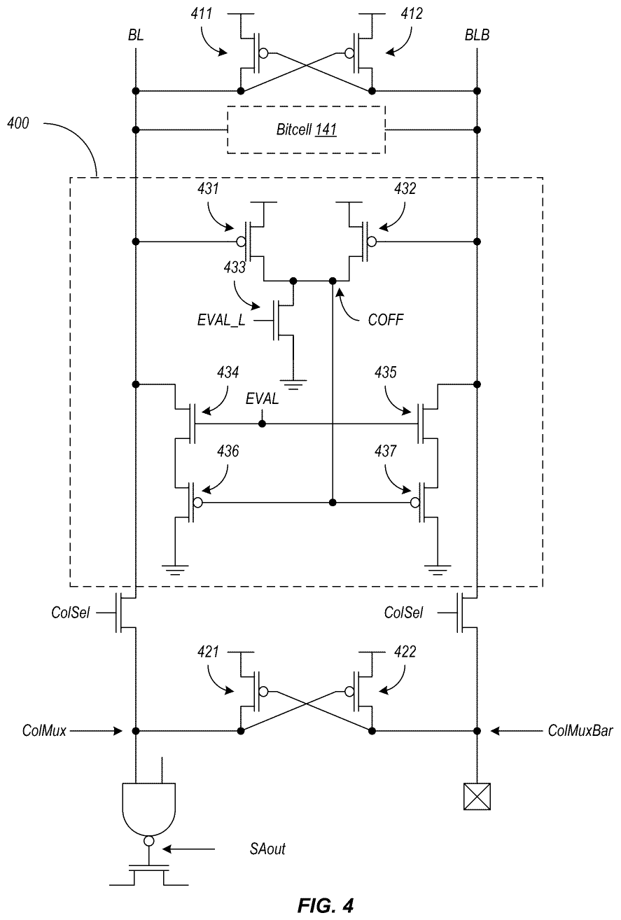

FIG. 4 is a block diagram illustrating an example memory in a first configuration, in accordance with one or more embodiments of the present disclosure. Bitcell 141 may be an example, embodiment, and/or implementation of bitcell 141 illustrated in FIG. 2.

The example memory of FIG. 4 also includes FETs 411, 412, 421, and 422. FETs 411 and 412 may be cross-coupled FETs that may maintain one of the lines BL and BLB high (e.g., a logical high, at a higher voltage, VDD, etc.) when the other line is low (e.g., logical low, at a lower voltage, VSS, etc.). For example, the FETs 411 and 412 may allow BLB to remain high when BL is low, and vice versa. The FETs 421 and 422 may be cross-coupled FETs that may maintain one of the nodes ColMux and ColMuxBar high (e.g., a logical high, at a higher voltage, VDD, etc.) when the other line is low (e.g., logical low, at a lower voltage, VSS, etc.).

The example memory of FIG. 4 also includes accelerated discharge circuit 400. Accelerated discharge circuit 400 includes FETs 431, 432, 433, 434, 435, 436, and 437. FETs 431, 432, 436, and 437 may be a PMOS FETs (e.g., pFET). FETs 433, 434, and 435 may be an NMOS FET (nFET). In one embodiment, prior to reading the bitcell 141, the BL and BLB lines may be precharged to VDD. The EVAL signal may be set to high (e.g., a higher voltage) which may turn on FETs 434 and 435 (e.g., allow current/voltage through) and the EVAL_L signal may be set to low (e.g., a lower voltage). The EVAL signal and EVAL_L signal, in some embodiments, are complementary signals. When EVAL_L is set low and EVAL is set high, the BL and BLB lines begin discharging from VDD to VSS through the FETs 434, 435, 436, and 437. As the BL and BLB lines discharge, the voltage on the BL and/or BLB lines may reach a threshold voltage VDDL. The threshold voltage is a voltage lower than VDD and higher than ground. In the example of FIG. 4, the VDDL threshold voltage is at or near a voltage that when crossed causes FET 432 and/or 433 to activate. When the BL and/or BLB lines reach the voltage VDDL, the FET 432 may turn on (e.g., may allow current/voltage through). This may cause the voltage at the node COFF to rise. When COFF rises, this may turn off FETs 436 and 437 (e.g., prevent current/voltage from flowing) which may cause the BL and/or BLB line to stop discharging.

In one embodiment, by dropping the BL line to the voltage VDDL, a processing device (or some other appropriate circuit/device) may be able to read the bitcell 141 more quickly if the bitcell 141 stores the value “0.” For example, when the bitcell 141 stores the value “0,” the BL line may drop to low (e.g., VSS) when the bitcell 141 is read. By dropping the BL line to the voltage VDDL before reading the bitcell 141, the BL line may be able to reach VSS more quickly, and thus, may be read more quickly by a processing device or some other device. The value that is stored in the bitcell 141 may be transmitted to SAout.

In one embodiment, the FETs 431, 432, 433, 434, 435, 436, and 437 may be used to decrease the amount of time for both single-ended reads (e.g., a read where only the BL line is read) and double ended reads (a read where both the BL and BLB lines are read) of the bitcell 141. In some embodiments, any of the FETs of the accelerated discharge circuit 400 may be implemented as an ultra-low voltage transistor.

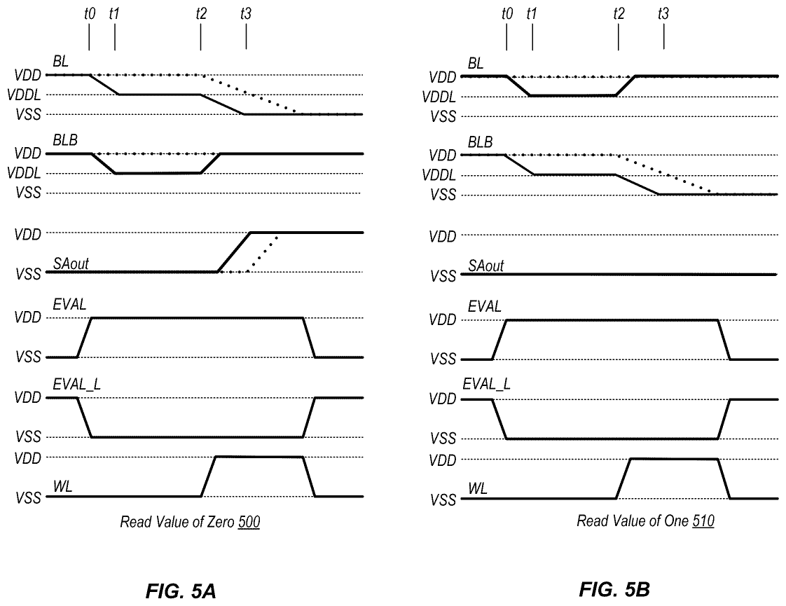

FIG. 5A and FIG. 5B set forth various timing diagrams related to the example memory of FIG. 4. FIG. 5A depicts a timing diagram illustrating an example accelerated read operation of the bitcell of the memory of FIG. 4 in which the value stored in the bitcell is a zero 500. To represent a value of zero stored in a bitcell, SAout will be at VDD.

In the example of FIG. 5A, BL and BLB have been precharged to VDD, EVAL is high and EVAL_L is low. With EVAL_L low, FET 433 is activated and couples the node COFF to ground. With COFF at ground, FETs 436 and 437 are activated.

At time to, EVAL transitions high and EVAL_L transitions low (deactivating FET 433 and decoupling COFF from ground). FETs 434 and 435 are activated by the EVAL transition high. With FETs 434, 435, 436, and 437 activated, BL and BLB are coupled to ground and begin discharging from t0 to t1 in the example timing diagram of FIG. 5A.

At time t1, BL and BLB reach a threshold voltage, VDDL, at which FETs 431 and 432 are activated. With FET 431 and 432 activated, node COFF is coupled to VDD. COFF will increase to a voltage level that deactivates the FETs 436 and 437 at time t2. COFF deactivating FETs 436 and 437 effectively bypasses the pull-down FETs 434, 435, 436, 437.

At time t2, WL transitions from low to high, which causes one of the bitlines to continue discharging through the typical operation of the bitcell 141 and based on the value stored in the bitcell. In the example of FIG. 5A, the value stored in the bitcell 141 is a zero. As such, the BL will continue discharging while BLB will return to VDD. Between time t2 and t3 BLB returns high and BLB completes discharge to VSS.

SAout, in the example of FIG. 5A, transitions from low to high between t2 and t3. This transition occurs more quickly than a conventional bitline read when the value stored within the bitcell is zero. The dotted lines in the example of FIG. 5A indicate signals of a memory that does not include an accelerated discharge circuit as described herein. As can be seen, for a memory that does not include an accelerated discharge circuit, BL does not begin to discharge until time t2. Likewise, for a memory that does not include an accelerated discharge circuit, SAout transitions high after time t3.

Embodiments described herein accelerate reading of a bitline when a bitcell stores a value of zero rather than a value of one. The accelerated discharge circuits described herein also ensure accurate reads of a bitcell that stores a value of one. For further explanation, FIG. 5B depicts a timing diagram illustrating an example read operation of the bitcell of the memory of FIG. 4 in which the value stored in the bitcell is a one 510.

Prior to t0, both BL and BLB are precharged to VDD and EVAL_L is high. At time to in the example of FIG. 5B, EVAL transitions from low to high and EVAL_L transitions from high to low. FETs 434 and 435 are activated by EVAL and FETs 436 and 437 are activated by COFF (which prior to t0 was pulled to ground via FET 433). BL begins discharging through FETs 434 and 436. BLB begins discharging through FETs 435 and 437.

To accurately reflect the value of one stored in the bitcell, BL must return to VDD. To that end, at time t1, BL reaches a predetermined threshold voltage VDDL. At VDDL, FET 431 and 432 are activated, coupling COFF to VDD. At time t2, COFF reaches a value that deactivates FETs 436 and 437, bypassing the FETs capability of discharging the BL and BLB bitlines. By time t3, BL has returned to VDD while BLB has dropped to a have a value of VSS. SAout reflects the proper value of one stored in the bitcell 141. When SAout is at VSS, the value in the bitcell is one.

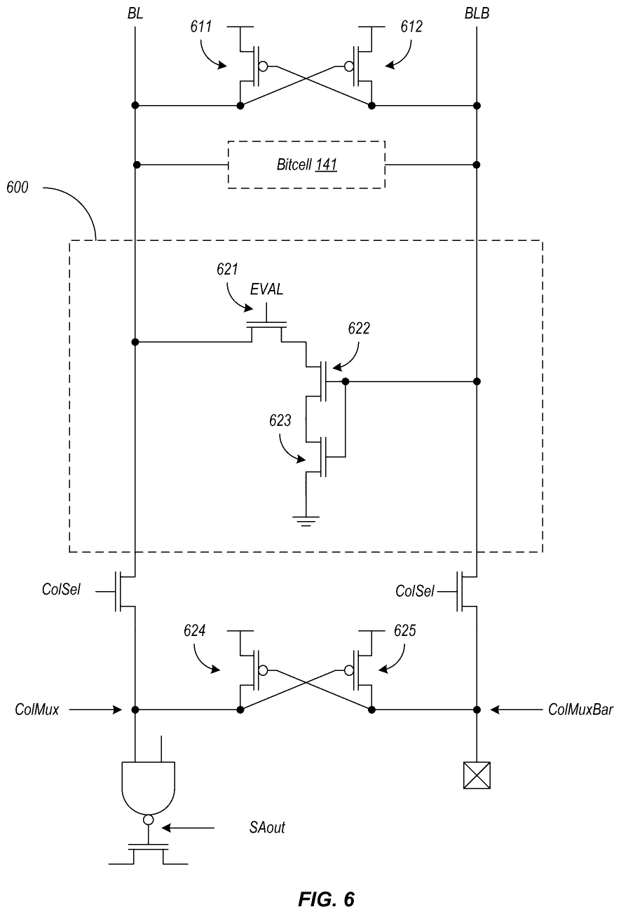

FIG. 6 is a block diagram illustrating an example memory in a second configuration, in accordance with one or more embodiments of the present disclosure. The example memory of FIG. 6 includes bitcell 141 which may be an example, embodiment, and/or implementation of bitcell 141 illustrated in FIG. 2. The example memory of FIG. 6 also includes a accelerated discharge circuit 600 that includes FETs 621, 622, and 623. FETs 621, 622, and 623 may be NMOS FETs (nFETs). In some embodiments, the FETs 622 and 623 may be replaced with a single FET whose gate is coupled to the BLB line.

The FETs 611 and 612 may be cross-coupled FETs that may maintain one of the lines BL and BLB high (e.g., a logical high, at a higher voltage, VDD, etc.) when the other line is low (e.g., logical low, at a lower voltage, VSS, etc.). For example, the FETs 611 and 612 may allow BLB to remain high when BL is low, and vice versa. The FETs 624 and 625 may be cross-coupled FETs that may maintain one of the nodes ColMux and ColMuxBar high (e.g., a logical high, at a higher voltage, VDD, etc.) when the other line is low (e.g., logical low, at a lower voltage, VSS, etc.).

In one embodiment, prior to reading the bitcell 141, the BL and BLB lines may be precharged to VDD. The EVAL signal may be set to high which may turn on FET 621. This may cause the BL line to be discharged from VDD to VSS through the FETs 622 and 623. If the bitcell 141 stores a “0” value, the BL line may discharge to VSS faster via the FETs 622 and 623 which may allow a processing device (or other device) to read the “0” value from the bitcell 141 more quickly. If the bitcell 141 stores a “1” value, the BLB line will drop to VSS which will turn off the FETs 622 and 623. Turning off the FETs 622 and 623 may prevent the BL line from discharging further and the BL line may charge back up to VDD, allowing the processing device to read the value “1”. The value that is stored in the bitcell 141 may be transmitted to SAout.

In one embodiment, the FETs 621, 622, and 623 may be used to decrease the amount of time for single-ended reads of the bitcell 141. In some embodiments, any of the FETs of the accelerated discharge circuit 600 may be implemented as an ultra-low voltage transistor.

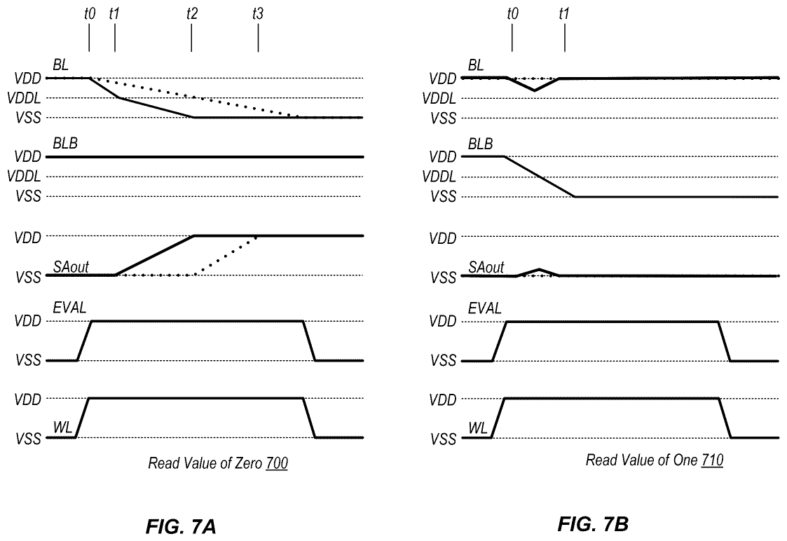

FIG. 7A and FIG. 7B set forth various timing diagrams related to the example memory of FIG. 6. FIG. 7A depicts a timing diagram illustrating an example accelerated read operation of the bitcell of the memory of FIG. 6 in which the value stored in the bitcell is a zero 700. In the example of FIG. 7A, BL and BLB have been precharged to VDD. With BL and BLB precharged to VDD, FETs 622 and 623 are activated. At time t0, both EVAL and WL transition to a logic high. The transition of EVAL to logic high activates FET 625 and couples BL to ground through pull-down FETs 622 and 623. Additionally, because the bitcell stores a value of a zero and WL is at a logic high, BL will be discharging in normal operation of the bitcell. As such, FIG. 7A depicts an accelerated discharge of BL between t0 and t1. As BL approaches VDDL at t1, the voltage differential across FETs 622 and 623 reduces and the discharging through those FETs is bypassed. Between time t1 and t2, BL continues to discharge but without the additional acceleration of the pull-down transistors 622 and 623.

SAout rises to VDD between time t1 and t2. Example signals for a memory without an accelerated discharge circuit are depicted as dotted lines. As can be seen, in a memory without an accelerated discharge circuit, BL takes longer to transition from high to low and SAout takes longer to transition from low to high. That is, reading the value of zero from the bitcell occurs more quickly in a memory configured with the accelerated discharge circuit described above in FIG. 6.

As mentioned above, embodiments described herein accelerate reading of a bitline when a bitcell stores a value of zero rather than a value of one. The accelerated discharge circuits described herein also ensure accurate reads of a bitcell that stores a value of one. For further explanation, FIG. 7B depicts a timing diagram illustrating an example read operation of the bitcell of the memory of FIG. 6 in which the value stored in the bitcell is a one 710.

Prior to t0, both BL and BLB are precharged to VDD. At time to, EVAL and WL transition from low to high. BL begins to discharge through FETs 621, 622, and 623. BLB also begins discharging as part of the normal operation of the bitcell 141 due to the fact that the bitcell stores a value of one. Between t0 and t1, BLB drops to a value that deactivates FETs 622 and 623, bypassing the discharge of BL through those FETs. As the bitcell 141 stores a value of one in this example, BL will return to VDD when not being actively discharged through the FETs. As can be seen between t0 and t1, BL drops a small amount and returns to VDD. In a similar manner, SAout has a small increase and returns to VSS. The small increase in SAout does not register as a value of a zero begin stored in the bitcell.

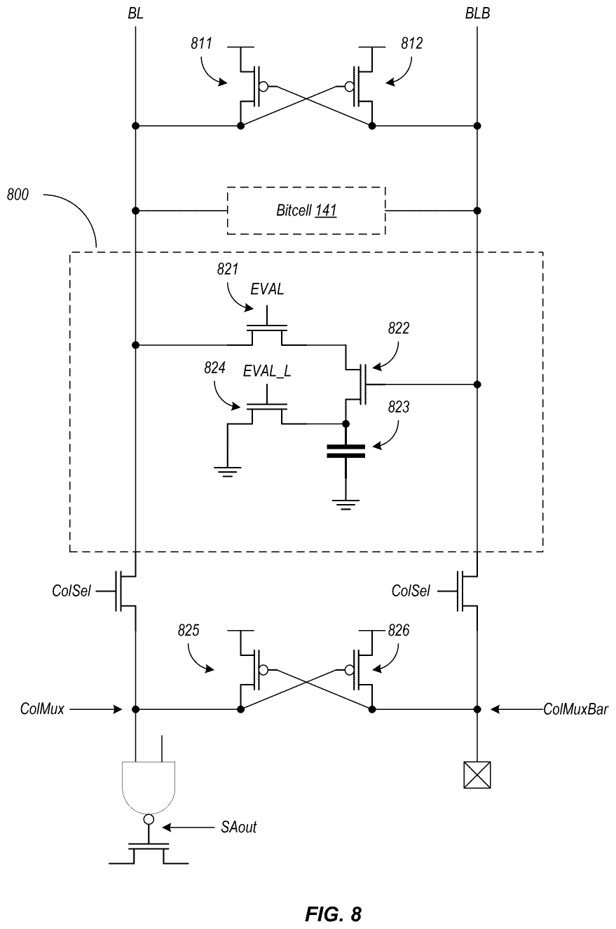

FIG. 8 is a block diagram illustrating an example memory in a third configuration, in accordance with one or more embodiments of the present disclosure. The example memory of FIG. 8 includes a bitcell 141 which may be an example, embodiment, and/or implementation of bitcell 141 illustrated in FIG. 2.

The FETs 811 and 812 may be cross-coupled FETs that may maintain one of the lines BL and BLB high (e.g., a logical high, at a higher voltage, VDD, etc.) when the other line is low (e.g., logical low, at a lower voltage, VSS, etc.). For example, the FETs 811 and 812 may allow BLB to remain high when BL is low, and vice versa. Additionally, the FETs 825 and 826 may be cross-coupled FETs that may maintain one of the nodes ColMux and ColMuxBar high (e.g., a logical high, at a higher voltage, VDD, etc.) when the other line is low (e.g., logical low, at a lower voltage, VSS, etc.).

The example memory of FIG. 8 also includes accelerated discharge circuit 800. Accelerated discharge circuit 800 includes FETs 821, 822, 824 and capacitor 823. In one embodiment, prior to reading the bitcell 141, the BL and BLB lines may be precharged to VDD. The EVAL signal may be set to high which may turn on FET 821 (e.g., allow current/voltage to pass through). This may cause the BL line to be discharged from the FETs 822 and capacitor 823. However, the capacitor 823 may prevent the BL line from discharging below a threshold voltage (e.g., a minimum voltage). For example, the capacitor 823 may maintain a threshold voltage for the BL line. If the bitcell 141 stores a “0” value, the BL line may discharge to VSS faster which may allow a processing device (or other device) to read the “0” value from the bitcell 141 more quickly. If the bitcell 141 stores a “1” value, the BLB line will drop to VSS which will turn off the FET 822. Turning off the FET 822 may prevent the BL line from discharging further and the BL line may charge back up to VDD, allowing the processing device to read the value “1”. The EVAL_L signal may be used to turn on the FET 824 which may discharge the capacitor 823 (e.g., may reset the capacitor 823). The value that is stored in the bitcell 141 may be transmitted to SAout.

In one embodiment, the FETs 821 822, 824, and capacitor 823 may be used to decrease the amount of time for single-ended reads of the bitcell 141. In some embodiments, any of the FETs of the accelerated discharge circuit 800 may be implemented as an ultra-low voltage transistor.

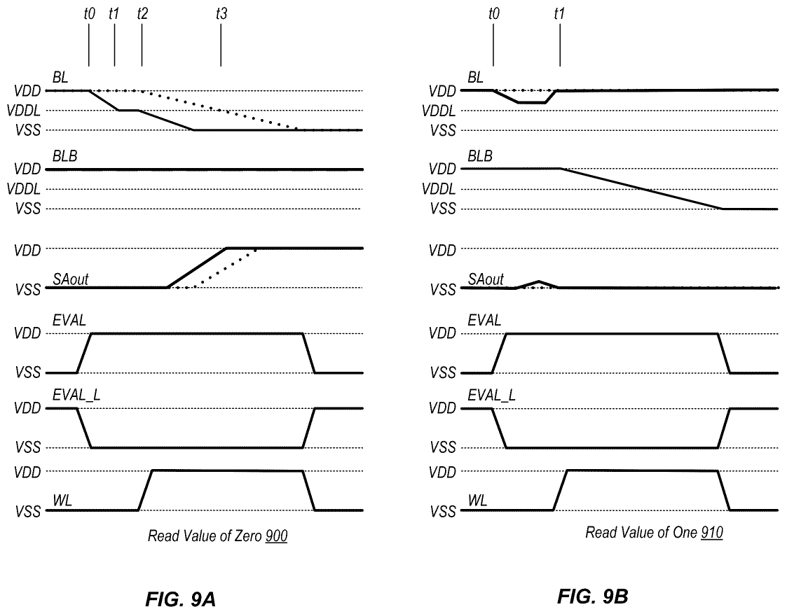

FIG. 9A and FIG. 9B set forth various timing diagrams related to the example memory of FIG. 8. FIG. 9A depicts a timing diagram illustrating an example accelerated read operation of the bitcell of the memory of FIG. 8 in which the value stored in the bitcell is a zero 900. In the example of FIG. 9A, BL and BLB have been precharged to VDD. With BL and BLB precharged to VDD, FET 822 is activated. At time t0, EVAL transitions to a logic high and EVAL_L transitions to logic low. As such, FET 821 is activated and FET 824 is opened. With FET 821 activated, BL is coupled through FET 821, FET 822, and capacitor 823 to ground and begins discharging.

At time t1, the value of BL drops to a threshold value VDDL and the capacitor 823 maintains a minimum voltage value as the voltage drop across FET 821 reduces. Eventually, the voltage at BL and the capacitor 823 will be the same. At time t2, WL transitions from low to high causing the bitcell to further discharge BL. As can be seen, at time t3, BL has dropped to VSS and SAout has transitioned to a logic high value to indicate that a zero is stored in the bitcell 141. As can also be seen, this transition occurs before a memory without an accelerated discharge circuit (signals depicted with dotted lines).

For further explanation, FIG. 9B depicts a timing diagram illustrating an example read operation of the bitcell of the memory of FIG. 8 in which the value stored in the bitcell is a one 910. Prior to t0, both BL and BLB are precharged to VDD. At time to, EVAL transitions from low to high and EVAL_L transitions from high to low. BL begins to discharge as described above while the capacitor begins sharing charge. BLB does not begin discharging until after t1 when WL transitions from low to high. Between t0 and t1, BLB is being pulled high by the bit cell and being discharged by the accelerated discharge circuit until BLB reaches a voltage matching (or nearly so) the voltage of the capacitor. Then, as BLB begins to discharge, FET 822 will be deactivated, and BLB will return to VDD. In this way, SAout has a small ‘bump’ in voltage between t0 and t1 that is lower than the threshold at which the value can be misinterpreted.

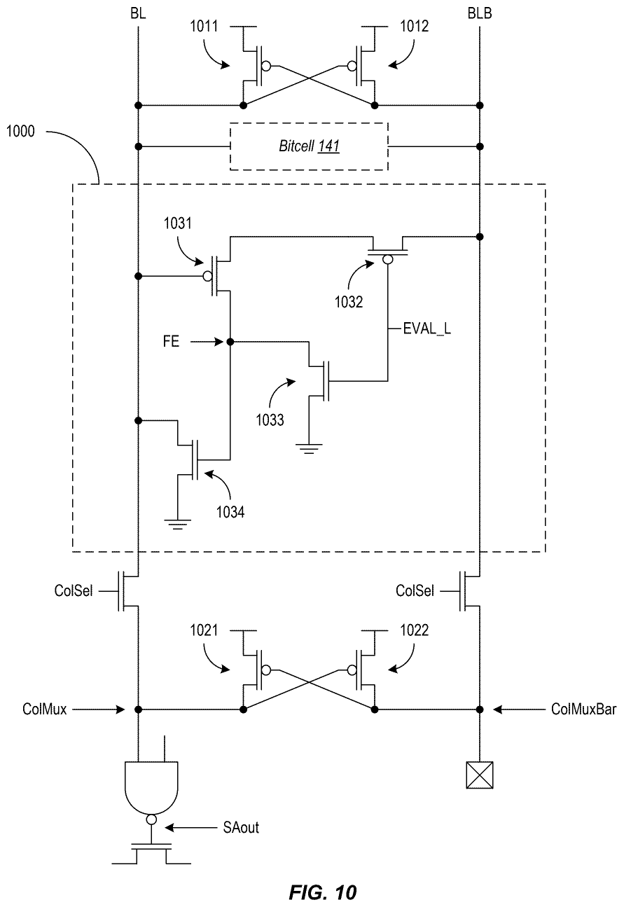

FIG. 10 is a block diagram illustrating an example memory in a fourth configuration, in accordance with one or more embodiments of the present disclosure. The example memory of FIG. 10 includes a bitcell 141 which may be an example, embodiment, and/or implementation of bitcell 141 illustrated in FIG. 2.

The example memory of FIG. 10 also includes FETs 1011, 1012, 1021, and 1022. FETs 1011 and 1012 may be cross-coupled FETs that may maintain one of the lines BL and BLB high (e.g., a logical high, at a higher voltage, VDD, etc.) when the other line is low (e.g., logical low, at a lower voltage, VSS, etc.). For example, the FETs 1011 and 1012 may allow BLB to remain high when BL is low, and vice versa. The FETs 1021 and 1022 may be cross-coupled FETs that may maintain one of the nodes ColMux and ColMuxBar high (e.g., a logical high, at a higher voltage, VDD, etc.) when the other line is low (e.g., logical low, at a lower voltage, VSS, etc.).

The example memory of FIG. 10 also includes a accelerated discharge circuit 1000 which includes FETs 1031, 1032, 1033, and 1034. In one embodiment, prior to reading the bitcell 141, the BL and BLB lines may be precharged to VDD. EVAL_L starts high (e.g., a high voltage) and may be set to low (e.g., a logical low) prior to the read. This may turn on the FET 1032 and may turn off the FET 1033. If the bitcell 141 stores the value “0,” when a processing device (or other device) begins to read the bitcell 141, the BL line will drop (e.g., the voltage on the BL line will drop). Once the BL line drops to a threshold voltage, the FET 1031 may turn on. When the FET 1031 turns on, the node FE will go high (e.g., go to a higher voltage). This may turn on the FET 1034, which will cause the BL line to go to VSS more quickly via the ground. If the bitcell 141 stores the value “1,” when a processing device (or other device) begins to read the bitcell 141, the BL line will remain high and the BLB line will go low (e.g., go to a lower voltage). The FE node will remain low, and the FET 1034 may remain off. FET 1031 also remains off.

In one embodiment, the FETs 1031, 1032, 1033, and 1034 may be duplicated (with a set of FETs) and mirrored on the BLB line and BL lines. The second set of FETs may be mirror the FETs 1031, 1032, 1033, and 1034 such that the second set of FETs may be used to cause the BLB line to go low (e.g., go to VSS or zero) more quickly.

In one embodiment, the FETs 431, 432, 434, 434, 435, 436, and 437 of FIG. 4 may be combined with the FETs 1031, 1032, 1033 and 1034 of FIG. 10. As discussed above, the FETs 431, 432, 433, 434, 435, 436, and 437 of FIG. 4 may decrease the voltage of the BL line prior to a read of the bitcell 141. This may allow the BL line to discharge more quickly which may allow a read of a “0” value to occur more quickly. The FETs 1031, 1032, 1033 and 1034 may increase the speed at which the BL line discharges during a read (rather than before). The speed for reading the value “0” may be further increased by using both the FETs 431, 432, 433, 434, 435, 436, and 437 of FIG. 4 and FETs 1031, 1032, 1033 and 1034 in the accelerated discharge circuit 1000. In some embodiments, any of the FETs of the accelerated discharge circuit 1000 may be implemented as an ultra-low voltage transistor.

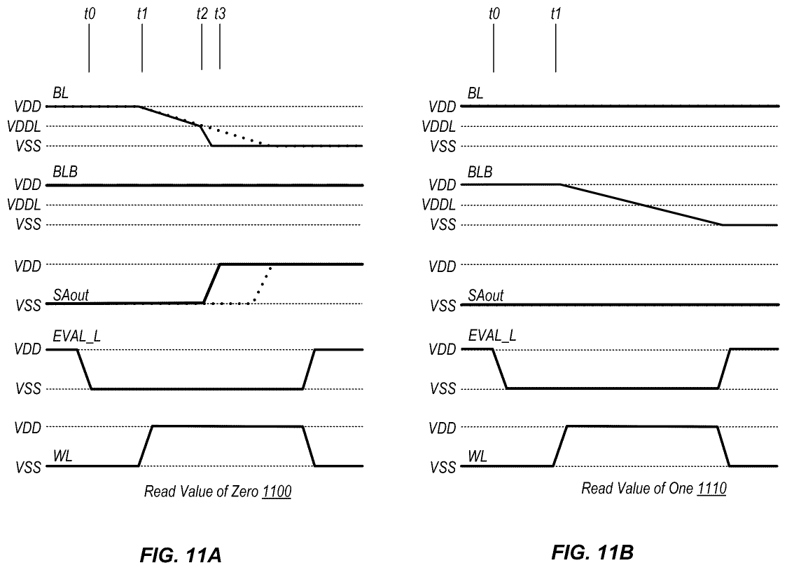

FIG. 11A and FIG. 11B set forth various timing diagrams related to the example memory of FIG. 10. FIG. 11A depicts a timing diagram illustrating an example accelerated read operation of the bitcell of the memory of FIG. 10 in which the value stored in the bitcell is a zero 1100. In the example of FIG. 11A, BL and BLB have been precharged to VDD.

At time to, EVAL_L transitions from high to low, causing FET 1032 to be activated and deactivating FET 1033. At time t1, WL transitions from low to high and BL begins to discharge in the normal operation of bitcell 141. When BL discharges to a predetermined threshold voltage VDDL, FET1031 is activated, coupling BL through FET 1032 and 1031 to node FE. As node FE rises, at time t2, FET 1034 is activated which couples BL through FET 1034 to ground, accelerating the discharge of BL. At time t3, BL has been completely discharged to VSS and SAout has transitioned between low to high. As can be seen both the discharge of BL and the transition of SAout occur before a memory without an accelerated discharge circuit (e.g., the signals depicted by as dotted lines).

FIG. 11B depicts a timing diagram illustrating an example accelerated read operation of the bitcell of the memory of FIG. 10 in which the value stored in the bitcell is a one 1110. In the example of FIG. 11B, BL and BLB have been precharged to VDD. At time t0, BL remains at VDD due to bitcell operation when EVAL_L transitions from high to low. At time t1, WL transitions from low to high and BLB begins discharging. There is no change in SAout and, as such, the accelerated discharge circuit does not affect the accuracy of reading a value of one 1110.

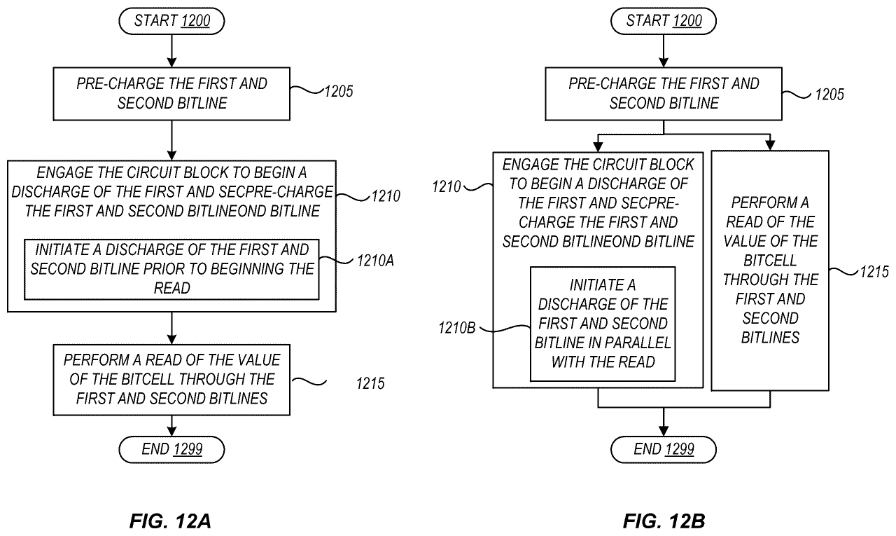

For further explanation, FIG. 12A and FIG. 12B each set forth a flow chart illustrating a method of an accelerated read of bitlines in memory. The method of FIG. 12A may be carried out with a memory that includes a first bitline, a second bitline, a bitcell coupled to the first and second bitlines and storing a value, and a accelerated discharge circuit coupled to the first and second bitlines. Such a memory may be implemented as the examples memories of FIGS. 4, 8, and 10.

The method of FIG. 12A begins at block 1200 and ends at block 1299. At block 1205, the method of FIG. 12A includes pre-charging the first and second bitline. Pre-charging the first and second bitline may be carried out by activating one or more transistors of the bitcell (such as N144 and N145 of bitcell 141 of FIG. 2).

At block 1210, the method continues by engaging the accelerated discharge circuit to begin a discharge of the first and second bitline. Engaging the accelerated discharge circuit may be carried out by asserting an evaluation signal (such as EVAL and its complement, in FIGS. 4, 8, and 10). In the method of FIG. 12A, at block 1210A, the discharge is initiated prior to the beginning of a read.

The method of FIG. 12A continues at bock 1215 by performing a read of the value of the bitcell through the first and second bitlines. A read may be performed by determining whether, after one of the bitlines discharges below a threshold (to ground, for example), which of the bitlines maintains a logic high and which was discharged to a logic low. If the first bitline, for example, discharges to a logic low while the second bitline remains a logic high, the value stored in the bitcell is a “0” value. If the second bitline, as another example, discharges to a logic low while the first bitline logic high, the value stored in the bitcell is a “1” value.

FIG. 12B may also be carried out with a memory that includes a first bitline, a second bitline, a bitcell coupled to the first and second bitlines and storing a value, and a accelerated discharge circuit coupled to the first and second bitlines. Such a memory may be implemented as the example memory of FIG. 6. The example method of FIG. 12B is similar to the example method of FIG. 12A. The example method of FIG. 12B includes, at block 1210B, initiating a discharge of the first and second bitline in parallel with the read. Initiating a discharge of the first and second bitline in parallel with the read may be carried out by asserting an evaluation signal (such as the EVAL signal in the example of FIG. 6) concurrently (or nearly so) with a word line signal (such as WL in the example bitcell 141 of FIG. 2).

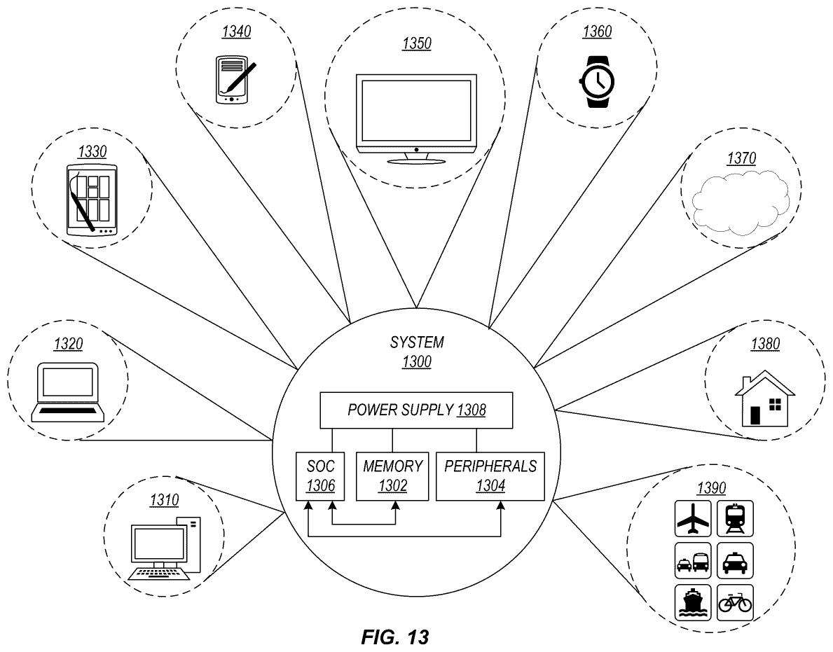

FIG. 13 is a block diagram of one embodiment of an example system 1300, in accordance with one or more embodiments of the present disclosure. The system 1300 may incorporate and/or otherwise utilize the methods, apparatuses, circuits, components, modules, and/or mechanisms described herein. In the illustrated embodiment, the system 1300 includes at least one instance of a system on chip (SoC) 1306 which may include multiple types of processing units, such as a central processing unit (CPU), a graphics processing unit (GPU), or otherwise, a communication fabric, and interfaces to memories and input/output devices. In some embodiments, one or more processors in SoC 1306 includes multiple execution lanes and an instruction issue queue. In various embodiments, SoC 1306 is coupled to external memory 1302, peripherals 1304, and power supply 1308. The SoC 1306 and/or the memory 1302 may include the example bitcells described herein.

A power supply 1308 is also provided which supplies the supply voltages to SoC 1306 as well as one or more supply voltages to the memory 1302 and/or the peripherals 1304. In various embodiments, power supply 1308 represents a battery (e.g., a rechargeable battery in a smart phone, laptop or tablet computer, or other device). In some embodiments, more than one instance of SoC 1306 is included (and more than one external memory 1302 is included as well).

The memory 1302 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 1304 include any desired circuitry, depending on the type of system 1300. For example, in one embodiment, peripherals 1304 includes devices for various types of wireless communication, such as Wi-Fi, Bluetooth, cellular, global positioning system, etc. In some embodiments, the peripherals 1304 also include additional storage, including RAM storage, solid state storage, or disk storage. The peripherals 1304 include user interface devices such as a display screen, including touch display screens or multitouch display screens, keyboard or other input devices, microphones, speakers, etc.

As illustrated, system 1300 is shown to have application in a wide range of areas. For example, system 1300 may be utilized as part of the chips, circuitry, components, etc., of a desktop computer 1310, laptop computer 1320, tablet computer 1330, cellular or mobile phone 1340, or television 1350 (or set-top box coupled to a television). Also illustrated is a smartwatch and health monitoring device 1360. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 1300 may further be used as part of a cloud-based service(s) 1370. For example, the previously mentioned devices, and/or other devices, may access computing resources in the cloud (i.e., remotely located hardware and/or software resources). Still further, system 1300 may be utilized in one or more devices of a home 1380 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 13 is the application of system 1300 to various modes of transportation 1390. For example, system 1300 may be used in the control and/or entertainment systems of aircraft, trains, buses, cars for hire, private automobiles, waterborne vessels from private boats to cruise liners, scooters (for rent or owned), and so on. In various cases, system 1300 may be used to provide automated guidance (e.g., self-driving vehicles), general systems control, and otherwise. These any many other embodiments are possible and are contemplated. It is noted that the devices and applications illustrated in FIG. 13 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” or is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation-[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement, The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. A circuit comprising:
a first bitline;
a second bitline;
a bitcell coupled to the first and second bitline and storing a value, the first and second bitlines charged to a logic high; and
an accelerated discharge circuit comprising one or more pull-down transistors and one or more bypass transistors, wherein the one or more pull-down transistors are configured to accelerate a discharge of the first and second bitlines and the bypass transistors are configured to bypass the pull-down transistors when at least one of the first and second bitline discharges to a predetermined threshold voltage.

2. The circuit of claim 1, wherein:
the one or more bypass transistors comprise a first pFET, a second pFET, and a first nFET;
the one or more pull-down transistors comprise a second nFET, a third nFET, a third pFET, and a fourth pFET;
the first pFET and the second pFET are coupled to the first nFET at a first node, the first pFET coupling a first voltage source to the first node when activated by the first bitline, the second pFET coupling the first voltage source to the first node when activated by the second bitline, and the first nFET couples the first node to ground when activated by a complement of an evaluation signal;
the second nFET is coupled to the third pFET at a second node, the second nFET coupling the first bitline to the second node when activated by the evaluation signal, the third pFET coupling the second node to ground when activated by the first node; and
the third nFET is coupled to the fourth pFET at a third node, the third nFET coupling the second bitline to the third node when activated by the evaluation signal, the fourth pFET coupling the third node to ground when activated by the first node.

3. The circuit of claim 1, wherein:
the one or more bypass transistors comprise a first nFET;
the one or more pull-down transistors comprise a second nFET and a third nFET;
the first nFET couples the first bitline to a first node when activated by an evaluation signal;
the second nFET couples the first node to a second node when activated by the second bitline; and
the third nFET couples the second node to ground when activated by the second bitline.

4. The circuit of claim 1, wherein:
the one or more pull-down transistors comprise a first nFET and a second nFET;
the one or more bypass transistors comprise a third nFET;
the first nFET couples the first bitline to a first node when activated by an evaluation signal;
the second nFET couples the first node to a second node when activated by the second bitline;
the third nFET couples the second node to ground when activated by a complement of the evaluation signal; and
a capacitor couples the second node to ground.

5. The circuit of claim 1, wherein:
the one or more pull-down transistors comprise a first nFET;
the one or more bypass transistors comprise a first pFET, a second pFET, and a second nFET;
the first pFET couples a first node to a second node when activated by the first bitline;
the second pFET couples the second bitline to the first node when activated by an evaluation signal;
the first nFET couples the first bitline to ground when activated by the second node; and
the second nFET couples the second node to ground when activated by the evaluation signal.

6. The circuit of claim 1, wherein one or more of transistors comprise ultra-low voltage transistors.

7. The circuit of claim 1, wherein the bitcell comprises a six-transistor cell.

8. An apparatus, comprising:
a control circuit; and
memory coupled to the control circuit, the memory comprising:
a first bitline;
a second bitline;
a bitcell coupled to the first and second bitline and storing a value; and
an accelerated discharge circuit coupled to the first and second bitline, wherein the control circuit is configured to:
pre-charge the first and second bitline;
engage the accelerated discharge circuit to begin a discharge of the first and second bitline; and
perform a read of the value of the bitcell through the first and second bitlines.

9. The apparatus of claim 8 wherein the accelerated discharge circuit comprises:
a first pFET and a second pFET coupled to a first nFET at a first node, wherein:
the first pFET couples a first voltage source to the first node when activated and the first pFET is activated by the first bitline;
the second pFET couples the first voltage source to the first node when activated and the second pFET is activated by the second bitline; and
the first nFET couples the first node to ground when activated, and the first nFET is activated by a complement of an evaluation signal;
a second nFET coupled to a third pFET at a second node, wherein:
the second nFET couples the first bitline to the second node when activated, and the second nFET is activated by the evaluation signal;
the third pFET couples the second node to ground when activated and the third pFET is activated by the first node; and
a third nFET coupled to a fourth pFET at a third node, wherein:
the third nFET couples the second bitline to the third node when activated, and the third nFET is activated by the evaluation signal; and
the fourth pFET couples the third node to ground when activated and the fourth pFET is activated by the first node.

10. The apparatus of claim 9, wherein the control circuit is configured to engage the accelerated discharge circuit to begin a discharge of the first and second bitline by asserting the evaluation signal prior to performing the read.

11. The apparatus of claim 8, wherein the accelerated discharge circuit comprises:
a first nFET, a second nFET, and a third nFET, wherein:
the first nFET couples the first bitline to a first node when activated and the first nFET is activated by an evaluation signal;
the second nFET couples the first node to a second node when activated and the second nFET is activated by the second bitline; and
the third nFET couples the second node to ground when activated and the third nFET is activated by the second bitline.

12. The apparatus of claim 11, wherein the control circuit is configured to engage the accelerated discharge circuit by asserting the evaluation signal in parallel with performing the read.

13. The apparatus of claim 8, wherein the accelerated discharge circuit comprises:
a first nFET, a second nFET, a third nFET, and a capacitor, wherein:
the first nFET couples the first bitline to a first node when activated and the first nFET is activated by an evaluation signal;
the second nFET couples the first node to a second node when activated and the second nFET is activated by the second bitline;
the third nFET couples the second node to ground when activated and the third nFET is activated by a complement of the evaluation signal; and
the capacitor couples the second node to ground.

14. The apparatus of claim 13, wherein the control circuit is configured to engage the accelerated discharge circuit by asserting the evaluation signal prior to performing the read.

15. The apparatus of claim 8, wherein the accelerated discharge circuit comprises:
a first pFET, a second pFET, a first nFET, and a second nFET, wherein:
the first pFET couples a first node to a second node when activated and the first pFET is activated by the first bitline;
the second pFET couples the second bitline to the first node when activated and the second pFET is activated by an evaluation signal;
the first nFET couples the first bitline to ground when activated and the first nFET is activated by the second node; and
the second nFET couples the second node to ground when activated and the second nFET is activated by the evaluation signal.

16. The apparatus of claim 15, wherein the control circuit is configured to engage the accelerated discharge circuit by asserting the evaluation signal prior to performing the read.

17. The apparatus of claim 8, wherein one or more of FETs of the accelerated discharge circuit comprise ultra-low voltage transistors.

18. A method of an accelerated read in a memory comprising a first bitline, a second bitline, a bitcell coupled to the first and second bitlines and storing a value, and a accelerated discharge circuit coupled to the first and second bitline, wherein the method comprises:
pre-charging the first and second bitline;
engaging the accelerated discharge circuit to begin a discharge of the first and second bitline; and
performing a read of the value of the bitcell through the first and second bitlines.

19. The method of claim 18, wherein engaging the accelerated discharge circuit further comprises initiating a discharge of the first and second bitline prior to beginning the read.

20. The method of claim 18, wherein engaging the accelerated discharge circuit further comprises initiating a discharge of the first and second bitline in parallel with the read.
